(19) United States
(12) Patent Application Publication
(10) Pub. No.: US 2023/0060697 A1
(43) Pub. Date: Mar. 2, 2023

(54) EUV RESIST UNDERLAYER FILM-FORMING COMPOSITION

(71) Applicant: NISSAN CHEMICAL CORPORATION, Tokyo (JP)

(72) Inventors: Shou SHIMIZU, Toyama-shi (JP); Hiroyuki WAKAYAMA, Toyama-shi (JP); Ryuta MIZUOCHI, Toyama-shi (JP); Mamoru TAMURA, Toyama-shi (JP)

(73) Assignee: NISSAN CHEMICAL CORPORATION, Tokyo (JP)

(21) Appl. No.: 17/790,324

(22) PCT Filed: Jan. 29, 2021
(86) PCT No.: PCT/JP2021/003122

§ 371 Date: Jun. 30, 2022

(30) Foreign Application Priority Data
Jan. 31, 2020 (JP) 2020-015094

(51) Int. Cl. G03F 7/11; G03F 7/00; G03F 7/16; G03F 7/20; G03F 7/38; H01L 21/027

(52) U.S. Cl. CPC G03F 7/11; G03F 7/0035; G03F 7/38; G03F 7/168; G03F 7/2004; H01L 21/0274

(57) ABSTRACT

A composition for forming a resist underlayer film that enables the formation of a desired resist pattern, a method for manufacturing a resist pattern using the composition for forming a resist underlayer film and a method for manufacturing a semiconductor device. This composition for forming an EUV resist underlayer film includes a polymer that contains a structure represented by formula (1) at an end [in formula (1): X¹ represents —O—, —S—, an ester bond or an amide bond; R¹ represents an optionally halogenated alkyl group having 1-20 carbon atoms; and * represents a binding portion to the polymer end] and an organic solvent.

### TECHNICAL FIELD

The present invention relates to a composition used in a lithography process in the production of a semiconductor, particularly in the state-of-the-art (ArF. EUV. EB, and the like) lithography process. In addition, the present invention relates to a method for producing a substrate having a resist pattern applied with the resist underlayer film, and a method for producing a semiconductor device.

### BACKGROUND ART

Conventionally, lithographic microfabrication using resist compositions has been used in the production of semiconductor devices. Microfabrication is a processing method which includes forming a thin film of photoresist composition on a semiconductor substrate such as silicon wafer, irradiating the film with active beams such as ultraviolet rays through a mask pattern on which a device pattern is drawn, developing this, and then performing etching treatment on the substrate with the obtained photoresist pattern as a protective film, thereby forming micro unevenness corresponding to said pattern on the substrate surface. In recent years, because semiconductor devices have become more highly integrated, as the active beams used, EUV light (wavelength: 13.5 nm) or EB (electron beams) for cutting-edge microfabrication has also been examined for application, in addition to the conventionally used i-line (wavelength of 365 nm). KrF excimer laser (wavelength: 248 nm), ArF excimer laser (wavelength: 193 nm). In line with this, the defects of resist pattern formation due to the influences from the semiconductor substrates and the like have become a major problem. To solve this problem, a method of providing a resist underlayer film between the resist and the semiconductor substrate has been widely examined.

Patent Literature 1 discloses a resist underlayer film material containing a hydroxy group as a base. Patent Literature 2 discloses a resist underlayer film-forming composition for lithography containing a polymers having an aromatic structure at a terminal.

### Citation List

### Patent Literature

Patent Literature 1: JP 2007-017950 A

Patent Literature 2: WO 2013/141015 A1

### SUMMARY OF INVENTION

### Technical Problem

The properties required for the resist underlayer film include, for example, not intermixing with the resist film formed on the upper layer (insoluble in resist solvent) and a higher dry etching speed than the resist film.

In the case of lithography with EUV exposure, the line width of the resist pattern formed is 32 nm or less, and the resist underlayer film for EUV exposure is formed to have a thinner film thickness than the conventional films and then is subjected for use. When forming such thin films, pinholes, agglomerations, and the like, easily occur due to the influences from the substrate surface and polymers used, making it difficult to form a uniform film without defects.

On the other hand, when forming a resist pattern, in the development step, a method which uses a solvent, generally an organic solvent, that could dissolve a resist film for removing an unexposed part of the resist film, and leaving the exposed part of the resist film as a resist pattern may be adopted. In such a negative development process, improving the adhesion of the resist pattern is a major issue.

In addition, it is desired to suppress the deterioration of LWR (Line Width Roughness) when forming a resist pattern, to form a resist pattern with a good rectangular shape, and to improve resist sensitivity.

An object of the present invention is to provide a composition for forming a resist underlayer film capable of forming a desired resist pattern and a resist pattern forming method using the resist underlayer film-forming composition, which allow to solve the above-mentioned problems.

### Solution to Problem

The present invention encompasses the followings.

An EUV resist underlayer film-forming composition comprising an organic solvent and a polymer comprising a structure of the following formula (1) at a terminal:

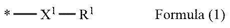

wherein, X¹ represents an —O—, —S. ester bond or amide bond, R¹ represents an alkyl group having 1 to 20 carbon atoms that may be substituted with a halogen atom; * denotes the binding site to the polymer terminal.

The EUV resist underlayer film-forming composition according to [1], wherein the polymer comprises a reactive group on a side chain.

The EUV resist underlayer film-forming composition according to [1] or [2], wherein the polymer comprises a unit structure represented by formula (2):

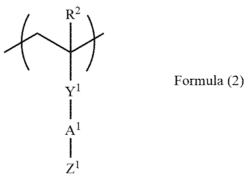

wherein. R² represents a hydrogen atom or an alkyl group having 1 to 5 carbon atoms; Y¹ represents a single bond, —O—. —S—, ester bond or amide bond; A¹ represents an alkylene group having 1 to 10 carbon atoms; and Z¹ represents a reactive group.

The EUV resist underlayer film-forming composition according to [2] or [3], wherein the reactive group is selected from the group consisting of a hydroxy group, an epoxy group, an acyl group, an acetyl group, a formyl group, a benzoyl group, a carboxy group, a carbonyl group, an amino group, an imino group, a cyano group, an azo group, an azide group, a thiol group, a sulfo group, and an allyl group.

The EUV resist underlayer film-forming composition according to any one of [1] to [4], further comprising a crosslinking catalyst.

The EUV resist underlayer film-forming composition according to any one of [1] to [5], further comprising a crosslinking agent.

An EUV resist underlayer film, which is a baked product of an applied film of the EUV resist underlayer film-forming composition according to any one of [1] to [6];

A method for producing a patterned substrate comprising:
applying and baking the EUV resist underlayer film-forming composition according to any one of [1] to [6] on a semiconductor substrate and thereby forming an EUV resist underlayer film;
applying and baking an EUV resist on the EUV resist underlayer film and thereby forming an EUV resist film;
exposing the EUV resist underlayer film and a semiconductor substrate coated with the EUV resist, and
developing the exposed EUV resist film and performing pattering.

A method for producing a semiconductor device comprising:
forming an EUV resist underlayer film consisting of the EUV resist underlayer film-forming composition according to any one of [1] to [6] on a semiconductor substrate;
forming an EUV resist film on the EUV resist underlayer film;
forming an EUV resist pattern by irradiating the EUV resist film with a light or electron beam followed by development;
forming a patterned EUV resist underlayer film by etching the EUV resist underlayer film through the formed EUV resist pattern, and
processing a semiconductor substrate by the patterned EUV resist underlayer film.

### Advantageous Effects of Invention

The EUV resist underlayer film-forming composition of the present invention comprises an organic solvent and a polymer comprising a structure of the following formula (1) at a terminal:

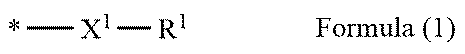

wherein, X¹ represents an —O—, —S. ester bond or amide bond; R¹ represents an alkyl group having 1 to 20 carbon atoms that may be substituted with halogen atoms.

The EUV resist underlayer film-forming composition of the present application, by adopting such constitution, can achieve suppression of LWR deterioration and improvement of sensitivity when forming a resist pattern.

### BREIF DESCRIPTOPN OF DRAWINGS

FIG. 1 is a scanning microscopic photograph taken from the upper side of the positive type resist pattern for EUV of Example 1.

FIG. 2 is a scanning microscopic photograph taken from the upper side of the positive type resist pattern for EUV of Comparative Example 1.

FIG. 3 is a scanning microscopic photograph taken from the upper side of the negative type resist pattern for EUV of Example 1.

FIG. 4 is a scanning microscopic photograph taken from the upper side of the negative type resist pattern for EUV of Comparative Example 1.

### DESCRIPTION OF EMBODIMENTS

### Definition of the Terms

Unless otherwise noted, the terms used in the present invention have the following definitions.

Examples of “alkyl groups having 1 to 20 carbon atoms” include a methyl group, an ethyl group, an n-propyl group, an i-propyl group, a cyclopropyl group, an n-butyl group, an i-butyl group, an s-butyl group, a t-butyl group, a cyclobutyl group, a 1-methyl-cyclopropyl group, a 2-methyl-cyclopropyl group, an n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, an n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, a 1-ethyl-2-methyl-n-propyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, a 2-ethyl-3-methyl-cyclopropyl group, a decyl group, a undecyl group, a dodecyl group, a tridecyl group, a tetradecyl group, a pentadecyl group, a hexadecyl group, a heptadecyl group, an octadecyl group, a nonadecyl group, an icosyl group, a norbornyl group, an adamantyl group, an adamantane methyl group, an anadamantane ethyl group, a cyclodecanyl group, a cycloundecanyl group, a cyclododecanyl group, a cyclotridecanyl group, cyclotetradecanyl group, a cyclopentadecanyl group, a cyclohexadecanyl group, a cycloheptadecanyl group, a cyclooctadecanyl group, a cyclononadecanyl group, and a cycloicosanyl group.

Examples of “alkylene groups having 1 to 10 carbon atoms” include a methylene group, an ethylene group, an n-propylene group, an isopropylene group, a cyclopropylene group, a n-butylene group, an isobutylene group, a s-butylene group, a t-butylene group, a cyclobutylene group, a 1-methyl-cyclopropylene group, a 2-methyl-cyclopropylene group, an n-pentylene group, a 1-methyl-n-butylene group, a 2-methyl-n-butylene group, a 3-methyl-n-butylene group, a 1,1-dimethyl-n-propylene group, a 1,2-dimethyl-n-propylene group, a 2,2-dimethyl-n-propylene group, a 1-ethyl-n-propylene group, a cyclopentylene group, a 1-methyl-cyclobutylene group, a 2-methyl-cyclobutylene group, a 3-methyl-cyclobutylene group, a 1,2-dimethyl-cyclopropylene group, a 2,3-dimethyl-cyclopropylene group, a 1-ethyl-cyclopropylene group, a 2-ethyl-cyclopropylene group, an n-hexylene group, a 1-methyl-n-pentylene group, a 2-methyl-n-pentylene group, a 3-methyl-n-pentylene group, a 4-methyl-n-pentylene group, a 1,1-dimethyl-n-butylene group, a 1,2-dimethyl-n-butylene group, a 1,3-dimethyl-n-butylene group, a 2,2-dimethyl-n-butylene group, a 2,3-dimethyl-n-butylene group, a 3,3-dimethyl-n-butylene group, a 1-ethyl-n-butylene group, a 2-ethyl-n-butylene group, a 1,1,2-trimethyl-n-propylene group, a 1,2,2-trimethyl-n-propylene group, a 1-ethyl-1-methyl-n-propylene group, a 1-ethyl-2-methyl-n-propylene group, a cyclohexylene group, a 1-methyl-cyclopentylene group, a 2-methyl-cyclopentylene group, a 3-methyl-cyclopentylene group, a 1-ethyl-cyclobutylene group, a 2-ethyl-cyclobutylene group, a 3-ethyl-cyclobutylene group, a 1,2-dimethyl-cyclobutylene group, a 1,3-dimethyl-cyclobutylene group, a 2,2-dimethyl-cyclobutylene group, a 2,3-dimethyl-cyclobutylene group, a 2,4-dimethyl-cyclobutylene group, a 3,3-dimethyl-cyclobutylene group, a 1-n-propyl-cyclopropylene group, a 2-n-propyl-cyclopropylene group, a 1-isopropyl-cyclopropylene group, a 2-isopropyl-cyclopropylene group, a 1,2,2-trimethyl-cyclopropylene group, a 1,2,3-trimethyl-cyclopropylene group, a 2,2,3-trimethyl-cyclopropylene group, a 1-ethyl-2-methyl-cyclopropylene group, a 2-ethyl-1-methyl-cyclopropylene group, a 2-ethyl-2-methyl-cyclopropylene group, a 2-ethyl-3-methyl-cyclopropylene group, an n-heptylene group, an-octylene group, an n-nonylene group, or an n-decanylene group.

Examples of halogen atoms include fluorine atom, chlorine atom, bromine atom and iodine atom.

### Resist Underlayer Film-Forming Composition

The EUV resist underlayer film-forming composition of the present invention comprises an organic solvent and a polymer comprising a structure of the following formula (1) at a terminal:

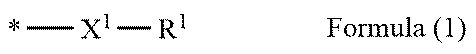

wherein, X¹ represents an —O—, —S, ester bond or amide bond; R¹ represents an alkyl group having 1 to 20 carbon atoms that may be substituted with a halogen atom; where ∗ denotes the binding site to the polymer terminal.

One or more hydrogen atoms of the above-mentioned alkyl groups having 1 to 20 carbon atoms may be substituted with the above-mentioned halogen atoms.

Of the above-mentioned alkyl groups, an alkyl group having 1 to 15 carbon atoms, an alkyl group having 4 to 15 carbon atoms, and an alkyl group having 4 to 12 carbon atoms are preferred. Also, linear alkyl groups without branching (methyl group, ethyl group, n-propyl group, n-butyl group, n-pentyl group, n-hexyl group, n-heptyl group, n-octyl group, n-nonyl group, n-decyl group, n-undecyl group, n-dodecyl group, n-tridecyl group, n-tetradecyl group, n-pentadecyl group, n-hexadecyl group, n-heptadecyl group, n-octadecyl group, n-nonadecyl group, and n-icosyl group) are preferred.

As polymers included in the EUV resist underlayer film-forming composition of the present application, known polymers such as olefin-reacted vinyl polymerization polymer, polyamide, polyester, polycarbonate, polyurethane, may be used, for example. However, olefin-reacted vinyl polymerization polymer or (meth)acrylic polymer polymerized with (meth)acrylate compound is particularly desirable. In the present invention, (meth)acrylate compounds mean both acrylate and methacrylate compounds. For example, (meth)acrylic acid means acrylic acid and methacrylic acid. The above-mentioned polymers may be produced by known methods.

The weight average molecular weight of the polymer is, for example, within the range of 2,000 to 50,000. The above-mentioned weight average molecular weight may be measured, for example, by gel permeation chromatography described in the Examples.

Examples of organic solvents included in the EUV resist underlayer film-forming composition include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate. 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxycyclopentane, anisole, γ-butyrolactone, N-methylpyrrolidone, N,N-dimethylformamide, and N.N-dimethylacetamide. These solvents may be used each alone or in combination of two or more.

Of these solvents, preferred are propylene glycol monomethyl ether, propylene glycol monomethyl ether acetate, ethyl lactate, butyl lactate, and cyclohexanone. Especially preferred are propylene glycol monomethyl ether and propylene glycol monomethyl ether acetate.

Preferably, the above-mentioned polymers contain a reactive group on a side chain.

The above-mentioned reactive groups are preferably selected from a hydroxy group, an epoxy group, an acyl group, an acetyl group, a formyl group, a benzoyl group, a carboxy group, a carbonyl group, an amino group, an imino group, a cyano group, an azo group, an azide group, a thiol group, a sulfo group, and an allyl group, of which a hydroxy group is preferred.

The above-mentioned polymer preferably include a unit structure represented by formula (2):

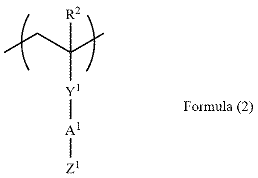

wherein, R² represents a hydrogen atom or an alkyl group having 1 to 5 carbon atoms; Y¹ represents a single bond, —O—, —S—, ester bond or amide bond; A¹ represents an alkylene group having 1 to 10 carbon atoms; and Z¹ represents a reactive group.

R² is preferably a hydrogen atom or a methyl group.

### Crosslinking Catalyst (Curing Catalyst)

Examples of crosslinking catalyst (curing catalyst) included as an optional ingredient in the resist underlayer forming composition of the present invention are, for example, sulfonic acid compounds and carboxylic acid compounds, such as p-toluenesulfonic acid, trifluoromethanesulfonic acid, pyridinium-p-loluenesulfonate (pyridinium-p-toluenesulfonate), pyridinium-p-hydroxybenzenesulfonic acid (p-phenolsulfonic acid pyridinium salt), pyridinium-trifluoromethanesulfonic acid, salicylic acid, camphorsulfonic acid, 5-sulfosalicylic acid, 4-chlorobenzenesulfonic acid, 4-hydroxybenzenesulfonic acid, benzenedisulfonic acid. 1-naphthalenesulfonic acid, citric acid, benzoic acid, hydroxybenzoic acid. When the above-mentioned crosslinking catalyst is used, the content ratio of said crosslinking catalyst is, for example, within the range of 0.1% to 50% by mass, preferably 1% to 30% by mass, of the crosslinking agent.

### Crosslinking Agent

Examples of the cross-linking agent included as an optional ingredient in the resist underlayer film-forming composition of the present invention are, for example, hexamethoxymethylmelamine, tetramethoxymethylbenzoguanamine 1,3,4,6-tetrakis(methoxymethyl)glycoluryl(tetramethoxymethylglycol uryl) (POWDERLINK [registered trademark] 1174). 1,3,4,6-tetrakis(butoxymethyl)glycoluryl, 1,3,4,6-tetrakis(hydroxymethyl)glycoluryl, 1,3-bis(hydroxymethyl)urea, 1,1,3,3-tetrakis(butoxymethyl)urea and 1,1,3,3-tetrakis(methoxymethyl)urea. When the above-mentioned crosslinking agent is used, the content ratio of the crosslinking agent is, for example, within the range of 1% by mass to 50% by mass, preferably 5% by mass to 30% by mass of the polymer.

### Other Components

A surfactant may be further added to the resist underlayer film-forming composition of the present invention to further improve the applicability to uneven surfaces without the occurrence of pinholes, striation, and the like. Examples of surfactants include nonionic surfactants, e.g., polyoxyethylene alkyl ethers, such as polyoxyethylene lauryl ether, polyoxyethylene stearyl ether, polyoxyethylene cetyl ether, and polyoxyethylene oleyl ether; polyoxyethylene alkyl aryl ethers, such as polyoxyethylene octyl phenol ether and polyoxyethylene nonyl phenol ether; polyoxyethylene-polyoxypropylene block copolymers; sorbitan fatty acid esters, such as sorbitan monolaurate, sorbitan monopalmitate, sorbitan monostearate, sorbitan monooleate, sorbitan trioleate, and sorbitan tristearate; and polyoxyethylene sorbitan fatty acid esters, such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine surfactants, such as EFTOP EF301, EF303, EF352 (Product Name: manufactured by Tohkem Products Corp.), MEGAFACE F171, F173, R-30 (Product Name: manufactured by Dainippon Ink and Chemicals, Inc.), Fluorad FC430, FC431 (Product Name: manufactured by Sumitomo 3M Ltd.), and AsahiGuard AG710, Surflon S-382, SC101, SC102. SC103, SC104, SC105, SC106 (Product Name: manufactured by Asahi Glass Co., Ltd.), and organosiloxane polymer KP341 (manufactured by Shin-Etsu Chemical Co., Ltd.). These surfactants are incorporated in an amount of generally less than 2.0% by mass, preferably less than 1.0% by mass, to the total solid content of the resist underlayer film-forming composition of the present invention. These surfactants may be added each alone or in combination of two or more.

### EUV Resist Underlayer Film

The resist underlayer film-forming composition of the present invention may be produced by applying the above-described resist underlayer film-forming composition onto a semiconductor substrate and baking the substrate.

Examples of semiconductor substrates to which the resist underlayer film-forming composition of the present invention is applied include a silicon wafer, a germanium wafer, and compound semiconductor wafers, such as gallium arsenide, indium phosphide, gallium nitride, indium nitride, and aluminum nitride.

When a semiconductor substrate having an inorganic film formed on the surface is used, the inorganic film is formed by, for example, an ALD (atomic layer deposition) method, a CVD (chemical vapor deposition) method, a reactive sputtering method, an ion plating method, a vacuum deposition method, or a spin coating method (spin on glass: SOG). Examples of the inorganic films include a polysilicon film, a silicon oxide film, a silicon nitride film, a BPSG (Boro-Phospho Silicate Glass) film, a titanium nitride film, a titanium nitride oxide film, a tungsten film, a gallium nitride film, and a gallium arsenide film.

The resist underlayer film-forming composition of the present invention is applied onto such semiconductor substrate by an appropriate application method, such as a spinner or a coater. Then, the applied composition is baked using a heating means, such as a hotplate, to form a resist underlayer film. The conditions for baking are appropriately selected from those at a baking temperature from 100 to 400° C. for a baking time from 0.3 to 60 minutes. Preferred conditions for baking are those at a baking temperature from 120 to 350° C. for a baking time from 0.5 to 30 minutes, and more preferred conditions are those at a baking temperature from 150 to 300° C. for a baking time from 0.8 to 10 minutes.

The film thickness of the EUV resist underlayer film formed is, for example, within the range of from 0.001 µm (1 nm) to 10 µm, from 0.002 µm (2 nm) to 1 um, from 0.005 µm (5 nm) to 0.5 µm (500 nm), from 0.001 µm (1 nm) to 0.05 µm (50 nm), from 0.002 µm (2 nm) to 0.05 µm (50 nm), from 0.003 µm (1 nm) to 0.05 µm (50 nm), from 0.004 µm (4 nm) to 0.05 µm (50 nm), from 0.005 µm (5 nm) to 0.05 µm (50 nm), from 0.003 µm (3 nm) to 0.03 µm (30 nm), from 0.003 µm (3 nm) to 0.02 µm (20 nm), and from 0.005 µm (5 nm) to 0.02 µm (20 nm). When the temperature at the baking stage is lower than the above range, cross-linking unsatisfactorily proceeds. To the contrary, when the temperature at baking stage is higher than the above range, the resist underlayer film may undergo decomposition due to heat.

### Methods for Producing a Patterned Substrate and Semiconductor Device

Methods for producing a patterned substrate involve the following steps. Usually, a patterned substrate is produced by forming a photoresist layer on top of an EUV resist underlayer film. There are no particular restriction as to the photoresist to be formed by coating and baking on the EUV resist underlayer film by a known method per se, as long as the photoresist is sensitive to the light used for exposure. Both negative type photoresist and positive type photoresist could be used. These include positive type photoresists composed of novolac resin and 1,2-naphthoquinone diazide sulfonic acid ester; chemically amplified type photoresists composed of a binder having a group that is degraded by acid to increase the alkali dissolution rate and a photoacid generator; chemically amplified type photoresists composed of a low molecular weight compound that is degraded by acid to increase the alkali dissolution rate of the photoresist, an alkaline soluble binder, and a photoacid generator; chemically amplified type photoresists composed of a binder having a group that is degraded by acid to increase the alkali dissolution rate of the photoresist, a low molecular weight compound that is degraded by acid to increase the alkali dissolution rate of the photoresist, and a photoacid generator; and resists containing metal elements. Examples include V146G (trade name) manufactured by JSR Corporation, APEX-E (trade name) manufactured by Shipley, PAR710 (trade name) manufactured by Sumitomo Chemical Co. Ltd.. AR2772, SEPR430 (trade names) manufactured by Shin-Etsu Chemical Co., Ltd. Furthermore, for example, fluoroatom-containing polymer-based photoresists that are disclosed in, Proc. SPIE, Vol.3999, 330-334(2000), Proc. SPIE, Vol.3999, 357-364(2000), and Proc. SPIE, Vol.3999, 365-374(2000), are included.

Moreover, although not limited thereto, the so-called resist compositions such as resist compositions, radiation-sensitive resin compositions, high-resolution patterning compositions based on organometallic solution, and metal-containing resist compositions disclosed in the following could be used: WO2019/188595, WO2019/187881, WO2019/187803, WO2019/167737, WO2019/167725, WO2019/187445, WO2019/167419, WO2019/123842, WO2019/054282, WO2019/058945, WO2019/058890, WO2019/039290, WO2019/044259, WO2019/044231, WO2019/026549, WO2018/193954A, WO2019/172054, WO2019/021975, WO2018/230334, WO2018/194123, JP2018-180525A, WO2018/190088, JP2018-070596A, JP2018-028090A, JP2016-153409A, JP2016-130240A, JP2016-108325A, JP2016-047920A, JP2016-035570A, JP2016-035567A, JP2016-035565A, JP2019-101417A, JP2019-117373A, JP2019-052294A, JP2019-008280A, JP2019-008279A, JP2019-003176A, JP2019-003175A, JP2018-197853A, JP2019-191298A, JP2019-061217A, JP2018-045152A, JP2018-022039A, JP2016-090441A, JP2015-10878A, JP2012-168279A, JP2012-022261A, JP2012-022258A, JP2011-043749A, JP2010-181857A, JP2010-128369A, WO2018/031896, JP2019-113855A, WO2017/156388, WO2017/066319, JP2018-41099A, WO2016/065120, WO2015/026482, JP2016-29498A, JP2011-253185A, and the like.

Resist compositions include, for example, the following:
An active light-sensitive or radiation-sensitive resin composition containing a resin A having a repeating unit having an acid degradable group whose polar group is protected by a protective group that is removed by the action of an acid, and a compound represented by the general formula (1): [Chemical Formula 6]

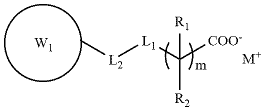

wherein, m represents an integer from 1 to 6.
R₁ and R₂ each independently represents a fluorine atom or a perfluoroalkyl group.
Li represents —O—. —S—, —COO—, —SO₂—, or —SO₃—.
L₂ represents an alkylene group that may have a substituent or a single bond.
W₁ represents a cyclic organic group that may have a substituent.
M⁺ represents a cation.

A metal-containing film-forming composition for extreme ultraviolet or electron beam lithography, containing a compound having a metal-oxygen covalent bond and a solvent, wherein the metal element constituting the above-mentioned compound belong to periods 3 to 7 of groups 3 to 15 of the periodic table.

A radiation-sensitive resin composition containing a polymer having a first structural unit represented by the following formula (1) and a second structural unit containing an acid-dissociating group represented by the following formula (2), and an acid generator: [Chemical Formula 7]

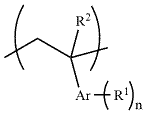

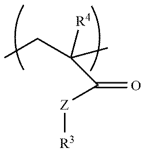

wherein, in formula (21). Ar is a group where (n+1) hydrogen atom is removed from an arene having 6 to 20 carbon atoms; R¹ is a hydroxy group, a sulfanyl group, or a monovalent organic group having 1 to 20 carbon atoms; n is an integer from 0 to 11; if n is 2 or more, a plurality of R¹ is identical or different; R² is a hydrogen atom, a fluorine atom, a methyl group or a trifluoromethyl group.

wherein, in formula (22), R³ is a monovalent group having a number of carbon of 1 to 20 containing the above-mentioned acid-dissociating group; Z is a single bond, an oxygen atom or a sulfur atom; R⁴ is a hydrogen atom, a fluorine atom, a methyl group or a trifluoromethyl group.

A resist composition containing a resin (A1) containing a structural unit having a cyclic carbonate ester structure, a structural unit represented by formula (II) and a structural unit represented by an acid unstable group, and an acid generator. [Chemical Formula 8]

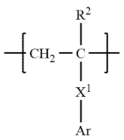

wherein, R² represents an alkyl group having 1 to 6 carbon atoms that may have a halogen atom, a hydrogen atom or a halogen atom, X¹ represents a single bond, —CO—O—* or —CO—NR⁴—*, where * represents a bonding hand with —Ar. R⁴ represents a hydrogen atom or an alkyl group having 1 to 4 carbon atoms, Ar represents an aromatic hydrocarbon group having 6 to 20 carbon atoms that may have one or more groups selected from the group consisting of a hydroxy group and a carboxyl group.

A resist composition that generates acid upon exposure and whose solubility in the developer is changed by the action of acid characterized by comprising: a base material component (A) whose solubility in the developer is changed by the action of acid and a fluorine additive component (F) that is degradable in an alkaline developer, wherein the fluorine additive component (F) contains the fluorine resin component (F1) having a structural unit (f1) containing a base-dissociating group and a structural unit (f2) containing a group represented by the following general formula (f2-r-1).

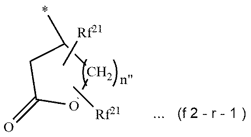

wherein, Rf²¹ is each independently a hydrogen atom, an alkyl group, an alkoxy group, a hydroxy group, a hydroxyalkyl group or a cyano group; n″ is an integer from 0 to 2, and * is a bonding hand.

wherein the structural unit (f1) includes a structural unit represented by the following general formula (fl-1) or a structural unit represented by the following general formula (f1-2):

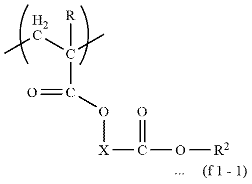

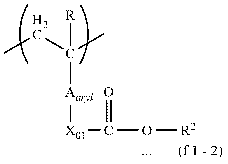

wherein, in formula (f1-1) and formula (f1-2), R is each independently a hydrogen atom, an alkyl group having 1 to 5 carbon atoms, or a halogenated alkyl group having 1 to 5 carbon atoms; X is a divalent linkage group without an acid-dissociating moiety; A_{aryl} is a divalent aromatic cyclic group that may have a substituent; X₀₁) is a single bond or a divalent linking group; R² are each independently an organic group having a fluorine atom.

The resist films include, for example, the following: A resist film containing a base resin containing a repeating unit represented by the following formula (a1) and/or a repeating unit represented by the following formula (a2), and a repeating unit that generates an acid bonded to the polymer main chain upon exposure. [Chemical Formula 11]

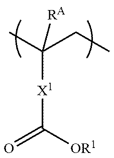

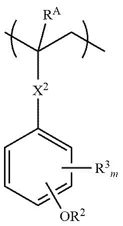

wherein, in formula (a1) and formula (a2), R^{A} is each independently a hydrogen atom or a methyl group; R¹ and R² are each independently a tertiary alkyl group having 4 to 6 carbon atoms; R³ is each independently a fluorine atom or a methyl group; m is an integer from 0 to 4; X¹ is a single bond, a phenylene group or naphthylene group, or a linkage group having 1 to 12 carbon atoms containing at least one kind selected from an ester bond, a lactone ring, a phenylene group and a naphthylene group; X² is a single bond, an ester bond or an amide bond.

The resist materials include, for example, the following.

A resist material containing a polymer having a repeating unit represented by the following formula (a1) or formula (a2): [Chemical Formula 12]

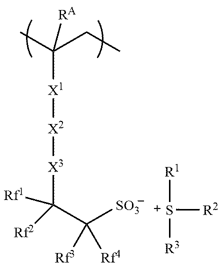

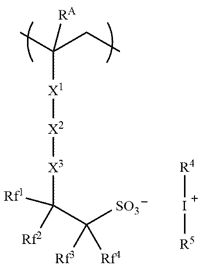

wherein, in formula (b1) and formula (b2). R^{A} is a hydrogen atom or a methyl group; X¹ is a single bond or an ester group; X² is a linear, branched or cyclic alkylene group having 1 to 12 carbon atoms or an arylene group having 6 to 10 carbon atoms, wherein a part of a methylene group constituting the alkylene group may be partially substituted with an ether group, an ester group or a lactone ring-containing group, and at least one hydrogen atom contained in X² is substituted with a bromine atom; X³ is a single bond, an ether group, an ester group, or a linear, branched or cyclic alkylene group having 1 to 12 carbon atoms, and a part of a methylene group constituting the alkylene group may be partially substituted with an ether group or an ester group; Rf¹ to Rf⁴ are each independently hydrogen atom, fluorine atom or trifluoromethyl group; however, at least one of them is a fluorine atom or a trifluoromethyl group. Moreover, Rf¹ and Rf² may also be combined to form a carbonyl group. R¹ to R⁵ are each independently a linear, branched or cyclic alkyl group having 1 to 12 carbon atoms, a linear, branched or cyclic alkenyl group having 2 to 12 carbon atoms, an alkynyl group having 2 to 12 carbon atoms, an aryl group having 6 to 20 carbon atoms, an aralkyl group having 7 to 12 carbon atoms or an aryloxyalkyl group having 7 to 12 carbon atoms, a part or all of the hydrogen atoms of these groups may be substituted with a hydroxy group, a carboxy group, an halogen atom, an oxo group, a cyano group, an amide group, a nitro group, a sultone group, a sulfone group or sulfonium salt-containing group, and a part of the methylene groups constituting these groups may be partially substituted with an ether, an ester, a carbonyl group, a carbonate group, or a sulfonate ester group; in addition, R¹ and R² may bind to form a ring together with the sulfur atom to which they are bonded.

A resist material containing a base resin containing a polymer having a repeating unit represented by the following formula (a): [Chemical Formula 13]

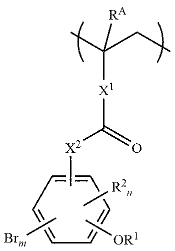

wherein, R^{A} is a hydrogen atom or a methyl group; R¹ is a hydrogen atom or an acid unstable group; R² is a linear, branched or cyclic alkyl group having 1 to 6 carbon atoms, or a halogen atom other than bromine; X¹ is a single bond or phenylene group, or a linear, branched or cyclic alkylene group having 1 to 12 carbon atoms which may contain an ester group or a lactone ring; X² is —O—, —O—CH₂— or —NH—; m is an integer from 1 to 4; n is an integer from 0 to 3.

The metal-containing resist compositions include, for example, the following: Coatings containing metal oxo-hydroxo networks having an organic ligand by metal-carbon bond and/or metal-carboxylate bond;

Inorganic oxo/hydroxo based compositions.

The coating solutions include, for example, the following: A coating solution containing an organic solvent; a first organometallic composition, represented by formula R_{z}SnO_{(2-(z/2)-(x/2)}(OH)ₓ (where 0<z≤2 and 0<(z+x)≤4), formula R’ₙSnX₄₋ₙ (where n=1 or 2) or mixtures thereof: wherein R and R′ are independently a hydrocarbyl group having 1 to 31 carbon atoms, and X is a ligand having a hydrolysable bond to Sn or a combination of them; and a hydrolysable metal compound, represented by the formula MX’ᵥ (wherein M is a metal selected from groups 2 to 16 of the periodic table of elements, v=2 to 6. and X′ is a ligand having a hydrolysable M-X bond or a combination of them).

A coating solution containing an organic solvent and a first organometallic compound represented by formula RSnO_{(3/2-x/2})(OH)ₓ (where 0<x<3), wherein the solution contains about 0.0025 M to 1.5 M of tin and R is an alkyl group or a cycloalkyl group having 3 to 31 carbon atoms and said alkyl or cycloalkyl group is bonded to tin via a secondary or tertiary carbon atom.

An inorganic pattern formation precursor aqueous solution containing a mixture of water, a metal suboxide cation, a polyatomic inorganic anion, and a radiation-sensitive ligand containing a peroxide group.

The exposure through a mask (reticle) for forming a predetermined pattern is conducted, and, an i-line, a KrF excimer laser, an ArF excimer laser, an EUV (extreme ultraviolet light), or an EB (electron beams) is used, for example. However, the resist underlayer film-forming composition of the present application is preferably applied for EUV (Extreme Ultraviolet) exposure. In development, an alkaline developer is used, and the conditions are appropriately selected from those at a development temperature from 5 to 50° C. for a development time from 10 to 300 seconds. A usable alkaline developer includes, for example, an aqueous solution of an alkali, e.g.. an inorganic alkali, such as sodium hydroxide, potassium hydroxide, sodium carbonate, sodium silicate, sodium metasilicate, or aqueous ammonia; a primary amine, such as ethylamine or n-propylamine; a secondary amine, such as diethylamine or di-n-butylamine; a tertiary amine, such as triethylamine or methyldiethylamine; an alcohol amine, such as dimethylethanolamine or triethanolamine; a quaternary ammonium salt, such as tetramethylammonium hydroxide, tetraethylammonium hydroxide, or choline; or a cyclic amine, such as pyrrole or piperidine. Further, the above-mentioned aqueous alkali solution to which alcohols, such as isopropyl alcohol, or surfactants, such as a nonionic surfactant, are added in an appropriate amount, may also be used. Of these, a preferred developer is a quaternary ammonium salt, and further preferred are tetramethylammonium hydroxide and choline. Further, for example, a surfactant and the like may be added to the above developer. A method, in which development is conducted using an organic solvent, such as butyl acetate, instead of an alkaline developer, to develop a portion with an unincreased alkali dissolution rate of the photoresist, may be used. By undergoing the above-mentioned steps, a substrate with the above-mentioned resist being patterned would be produced.

Then, using the formed resist pattern as a mask, the resist underlayer film is subjected to dry etching. In this instance, when the above-mentioned inorganic film is formed on the surface of the semiconductor substrate used, the surface of the inorganic film is exposed; and, when the inorganic film is not formed on the surface of the semiconductor substrate used, the surface of the semiconductor substrate is exposed. Then, the substrate may be processed by a substrate processing step by a method known per se (dry etching method, and the like), to produce a semiconductor device.

### Examples

The following examples specifically illustrate the present invention in detail, but the present invention is not limited to these examples.

The weight average molecular weights of the polymers shown in the below-mentioned Synthesis Example 1 and Comparative Synthesis Example 1 of the present specification are the results measured by gel permeation chromatography (hereinafter referred to as GPC). A GPC apparatus manufactured by Tosoh Corp. was used for the measurement, and the measurement conditions were as follows.

GPC Column: Shodex KF803L, Shodex KF802, Shodex KF801 [registered trademark]

(Showa Denko K.K.)

Column temperature: 40° C.

Solvent: tetrahydrofuran (THF)

Flow rate: 1.0 mL/minute

Standard sample: Polystyrene (Manufactured by Tosoh Corp.)

### Synthesis Example 1

125.00 g of hydroxyethyl methacrylate (manufactured by Tokyo Kasei Kogyo Co., Ltd.) , 22.78 g of azobisisobutyronitrile (manufactured by Tokyo Kasei Kogyo Co., Ltd.) , 3.15 g of ethyltriphenylphosphonium bromide (manufactured by ACROSS) and 9.72 g of dodecanethiol (manufactured by Tokyo Kasei Kogyo Co.. Ltd.) were added to 321.71 g of propylene glycol monomethyl ether and dissolved. After replacing the reaction vessel with nitrogen, the reaction was carried out at 80° C. for 24 hours to obtain a polymer solution. The polymer solution did not become cloudy, when cooled to room temperature, and had a good solubility in propylene glycol monomethyl ether. GPC analysis showed that the polymer in the obtained solution had a weight average molecular weight of 5000 as determined by standard polystyrene conversion and a degree of dispersion of 1.62. The polymer obtained in this synthetic example has the structural unit represented by the following formula (1a). [Chemical Formula 14]

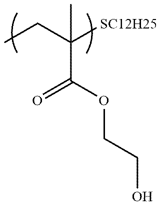

### Comparative Synthesis Example 1

10.00 g of t-butoxymethacrylate (manufactured by Tokyo Kasei Kogyo Co.. Ltd.) , 6.10 g of 2-hydroxyethyl methacrylate (manufactured by Tokyo Kasei Kogyo Co., Ltd.), and 0.96 g of azobisisobutyronitrile (manufactured by Tokyo Kasei Kogyo Co., Ltd.) were added to 73.00 g of propylene glycol monomethyl ether and dissolved. After replacing the reaction vessel with nitrogen, the reaction was carried out at 80° C. for 24 hours to obtain the polymer solution. The polymer solution did not become cloudy, when cooled to room temperature, and had a good solubility in propylene glycol monomethyl ether. GPC analysis showed that the polymer in the obtained solution had a weight average molecular weight of 3690 as determined by standard polystyrene conversion and a degree of dispersion of 2.25. The polymer obtained in this synthetic example has the structural unit represented by the following formula (1b) and formula (2b). [Chemical Formula 15]

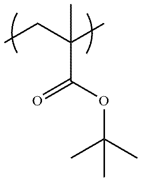

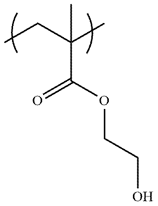

### Example 1

To 3.12 g of a polymer solution containing 0.047 g of the polymer obtained in Synthesis Example 1 above, 0.11 g of tetramethoxymethylglycol uryl (manufactured by Japan Cytec Industries Inc.) and 0.012 g of p-phenolsulfonic acid pyridinium salt (manufactured by Tokyo Kasei Kogyo Co., Ltd.) were mixed; and 263.41 g of propylene glycol monomethyl ether and 29.89 g propylene glycol monomethyl ether acetate were added thereto and dissolved. Thereafter, the resulting solution was filtered with a polyethylene microfilter having a pore diameter of 0.05 µm, to prepare an EUV resist underlayer film-forming composition.

### Comparative Example 1

To 3.12 g of a polymer solution containing 0.047 g of the polymer obtained in Comparative Synthesis Example 1 above. 0.11 g of tetramethoxymethylglycol uryl (manufactured by Japan Cytec Industries Inc.) and 0.012 g of p-phenolsulfonic acid pyridinium salt (manufactured by Tokyo Kasei Kogyo Co.. Ltd.) were mixed; and 263.41 g of propylene glycol monomethyl ether and 29.89 g of propylene glycol monomethyl ether acetate were added thereto and dissolved. Thereafter, the resulting solution was filtered with a polyethylene microfilter having a pore diameter of 0.05 µm, to prepare an EUV resist underlayer film-forming composition.

### Elution Test in Photoresist Solvent

Each of the resist underlayer film-forming compositions of Example 1 and Comparative Example 1 was applied to a silicon wafer, which is a semiconductor substrate, by a spinner. The silicon wafer was placed on a hot plate and baked at 215° C. for 1 minute, to form a resist underlayer film (5 nm film thickness). These resist underlayer films were immersed in each of ethyl lactate and propylene glycol monomethyl ether, which are solvents used for photoresists, and these resist underlayer films were confirmed to be insoluble in those solvents.

### Positive Type Resist Pattern Formation by Electron Beam Lithography Device

Each of the resist underlayer film-forming compositions of Example 1 and Comparative Example 1 was applied on a silicon wafer using a spinner. The silicon wafer was placed on a hot plate and baked at 215° C. for 60 minutes, to obtain a resist underlayer film of a film thickness of 5 nm. The positive type resist solution for EUV was spin-coated on the resist underlayer film, and heated at 100° C. for 60 seconds, to form the EUV resist film. The resist film was exposed to an electron beam lithography device (ELS-G130) under predetermined conditions. After the exposure, baking (PEB) was performed at 110° C. for 60 seconds and cooled to room temperature on a cooling plate. After development with alkaline developer (2.38% TMAH), a resist pattern with 25 nm line/50 nm pitch was formed. A scanning electron microscope (CG4100, manufactured by Hitachi High-Technologies Corporation) was used to measure the length of the resist pattern. The exposure amount that formed 25 nm line/50 nm pitch (line and space (L/S=1/1)) in the above resist pattern formation was taken as the optimal exposure amount.

The resulting photoresist pattern was observed from the upper side of the pattern and evaluated. A resist pattern that formed well was rated as “good”, and an undesirable state, in which the resist pattern peeled off and collapsed, was rated as “collapsed”.

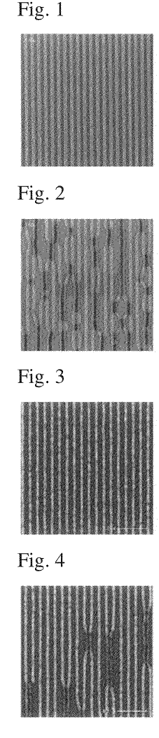

The obtained results are shown in Table 1. Also, the scanning microscopic photograph (upper side of the pattern) of resist patterns in which the composition of Example 1 was applied and the scanning microscopic photograph in which the composition of Comparative Example 1 was applied are shown in FIGS. 1 and 2, respectively.

Table 1

| | |
|---|---|
| | 25 nm line |
| Example 1 | Good |
| Comparative Example 1 | Collapsed |

### Negative Type Resist Pattern Formation by Electron Beam Lithography Device

Each of the resist underlayer film-fonning compositions of Example 1 and Comparative Example 1 was applied on a silicon wafer using a spinner. The silicon wafer was placed on a hot plate and baked at 215° C. for 60 minutes, to obtain a resist underlayer film of a film thickness of 5 nm. The negative type resist solution for EUV was spin-coated on the resist underlayer film, and heated at 100° C. for 60 seconds, to form the EUV resist film. The resist film was exposed under predetermined conditions using an electron beam lithography device (ELS-G130). After the exposure, baking (PEB) was performed at 110° C. for 60 seconds and cooled to room temperature on a cooling plate. After the development with butyl acetate, a resist pattern with 25 nm line/50 nm pitch was formed. A scanning electron microscope (CG4100, manufactured by Hitachi High-Technologies Corporation) was used to measure the length of the resist pattern. The exposure amount that formed 25 nm line/50 nm pitch (line and space (L/S=1/1)) in the above resist pattern formation was taken as the optimal exposure amount.

The resulting photoresist pattern was observed from the upper side of the pattern and evaluated. A resist pattern that formed well with the same exposure amount was rated as “good”, and a resist pattern with residuals existing between patterns was rated as “defects”.

The obtained results are shown in Table 1. Also, the scanning microscopic photograph (upper side of the pattern) of resist patterns in which the composition of Example 1 was applied and the scanning microscopic photograph in which the composition of Comparative Example 1 was applied are shown in FIGS. 3 and 4, respectively.

Table 2

| | |
|---|---|
| | 25 nm line |
| Example 1 | Good |
| Comparative Example 1 | Collapsed |

### Industrial Applicability

The resist underlayer film-forming composition of the present invention can provide a composition for forming a resist underlayer film capable of forming a desired resist pattern as well as a method for producing a substrate having a resist pattern using the resist underlayer film-forming composition, and a method for producing a semiconductor device.

1. An EUV resist underlayer film-forming composition comprising an organic solvent and a polymer comprising a structure of the following formula (1) at a terminal: 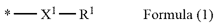
wherein, X¹ represents an —O—, —S, ester bond or amide bond; R¹ represents an alkyl group having 1 to 20 carbon atoms that may be substituted with a halogen atom; * denotes the binding site to the polymer terminal.

2. The EUV resist underlayer film-forming composition according to claim 1, wherein the polymer comprises a reactive group on a side chain.

3. The EUV resist underlayer film-forming composition according to claim 1, wherein the polymer comprises a unit structure represented by formula (2): 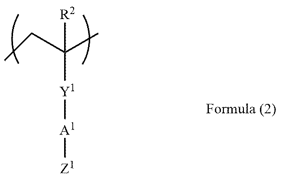
wherein, R² represents a hydrogen atom or an alkyl group having 1 to 5 carbon atoms; Y¹ represents a single bond, —O—, —S—, ester bond or amide bond; A¹ represents an alkylene group having 1 to 10 carbon atoms; and Z¹ represents a reactive group.

4. The EUV resist underlayer film-forming composition according to claim 2, wherein the reactive group is selected from the group consisting of a hydroxy group, an epoxy group, an acyl group, an acetyl group, a formyl group, a benzoyl group, a carboxy group, a carbonyl group, an amino group, an imino group, a cyano group, an azo group, an azide group, a thiol group, a sulfo group, and an allyl group.

5. The EUV resist underlayer film-forming composition according to claim 1, further comprising a crosslinking catalyst.

6. The EUV resist underlayer film-forming composition according to claim 1, further comprising a crosslinking agent.

7. An EUV resist underlayer film, which is a baked product of an applied film of the EUV resist underlayer film-forming composition according to claim 1.

8. A method for producing a patterned substrate comprising:
applying and baking the EUV resist underlayer film-forming composition according to claim 1 on a semiconductor substrate and thereby forming an EUV resist underlayer film;
applying and baking an EUV resist on the EUV resist underlayer film and thereby forming an EUV resist film;
exposing the EUV resist underlayer film and a semiconductor substrate coated with the EUV resist, and
developing the exposed EUV resist film and performing pattering.

9. A method for producing a semiconductor device comprising:
forming an EUV resist underlayer film consisting of the EUV resist underlayer film-forming composition according to claim 1 on a semiconductor substrate;
forming an EUV resist film on the EUV resist underlayer film;
forming an EUV resist pattern by irradiating the EUV resist film with a light or electron beam followed by development;
forming a patterned EUV resist underlayer film by etching the EUV resist underlayer film through the formed EUV resist pattern, and
processing a semiconductor substrate by the patterned EUV resist underlayer film.
